(19) United States
(12) Patent Application Publication
(10) Pub. No.: US 2006/0278937 A1
(43) Pub. Date: Dec. 14, 2006

(54) Semiconductor device and manufacturing method of the same

(76) Inventors: Masaru Kadoshima, Tsukuba (JP); Toshihide Nabatame, Tsukuba (JP); Akira Toriumi, Yokohama (JP)

Correspondence Address: REED SMITH LLP, Suite 1400, 3110 Fairview Park Drive, Falls Church, VA, 22042, US

(21) Appl. No.: 11/448,110

(22) Filed: Jun. 7, 2006

(30) Foreign Application Priority Data
Jun. 8, 2005 (JP) JP2005-167903

(51) Int. Cl. H01L 29/76

(52) U.S. Cl. 257/384

(57) ABSTRACT

As shown in FIG. 2B, a gate electrode is formed on a gate insulating film on a semiconductor substrate. A high dielectric film with a dielectric constant higher than that of a silicon oxide film is used for the gate insulating film, and a platinum-rich silicide film is used for the gate electrode. The platinum-rich silicide film indicates a film with a ratio of silicon atoms to platinum atoms of less than 1 (PtSix: x<1). Boron as a conductive impurity is introduced to the gate electrode composed of the platinum-rich silicide film, and the boron is segregated at an interface between the gate insulating film and the gate electrode.

### CROSS-REFERENCE TO RELATED APPLICATION

The present application claims priority from Japanese Patent Application No. JP 2005-167903 filed on Jun. 8, 2005, the content of which is hereby incorporated by reference into this application.

### TECHNICAL FIELD OF THE INVENTION

The present invention relates to a semiconductor device and a manufacturing technology thereof. More particularly, it relates to a technology effectively applied to a semiconductor device including a metal insulator semiconductor field effect transistor (MISFET) in which a gate electrode is formed on a hafnium-based (Hf-based) gate insulating film.

### BACKGROUND OF THE INVENTION

U.S. Pat. No. 6,599,831 B1 (Patent Document 1) describes a MISFET in which a gate electrode is formed on a gate insulating film formed of a silicon oxide film. More specifically, a fully-silicided electrode is used as a gate electrode and a threshold voltage of the MISFET is controlled by means of dopant.

In recent years, the use of a high dielectric film with a dielectric constant higher than that of a silicon oxide film as a gate insulating film instead of a silicon oxide film has been considered. In this case, it has been reported that a Fermi level (work function) of a gate electrode formed of a polysilicon film shifts from a Fermi level available on a silicon oxide film in a direction where a threshold value of a MISFET increases. This phenomenon is known as Fermi level pinning (IEEE TRANSACTIONS ON ELECTRON DEVICES, VOL. 51, No. 6, June 2004, pp. 971-984 (Non-Patent Document 1)).

### SUMMARY OF THE INVENTION

Conventionally, in a n channel MISFET and a p channel MISFET which constitute a complementary metal insulator semiconductor (CMIS) circuit, a silicon oxide film has been used as a gate insulating film.

In recent years, however, along with the scaling down of MISFETs constituting a semiconductor device, the thickness of a gate insulating film has been rapidly reduced. When the thickness of a gate insulating film is reduced, electrons penetrate the gate insulating film due to the tunneling effect, which makes the tunneling current flow through the gate insulating film. Consequently, the leakage current of the MISFET is increased.

For its prevention, the replacement of a gate insulating film material from a silicon oxide film to a high dielectric film with a dielectric constant higher than that of a silicon oxide film has been considered. This is because, when the high dielectric film is used to form the gate insulating film, the actual physical thickness can be increased “dielectric constant of high dielectric film/dielectric constant of silicon oxide film” times while keeping the same capacitance as that of the case where a silicon oxide film is used to form the gate insulating film, and accordingly, the leakage current can be reduced. As the materials of the high dielectric film, metal oxides such as hafnium (Hf) oxide and zirconium (Zr) oxide have been examined.

As described above, the leakage current through a gate insulating film can be reduced by using a high dielectric film as a gate insulating film of a MISFET. However, new problems arise.

Conventionally, in a n channel MISFET and a p channel MISFET, a polysilicon film is used as a gate electrode. Also, a n type impurity (for example, phosphorus and arsenic) is introduced to the polysilicon film of the gate electrode in the n channel MISFET. By this means, the work function (Fermi level) of the gate electrode is set near the conduction band (4.05 eV) of silicon so as to reduce the threshold voltage of the n channel MISFET. Meanwhile, a p type impurity (for example, boron) is introduced to the polysilicon film of the gate electrode in the p channel MISFET. By this means, the work function of the gate electrode is set near the valence band (5.17 eV) of silicon so as to reduce the threshold voltage of the p channel MISFET. This is an example when a silicon oxide film is used as a gate insulating film. More specifically, in the case where a silicon oxide film is used as a gate insulating film, the work function of the gate electrode can be set near the conduction band or the valence band by introducing a n type impurity or a p type impurity to the gate electrode.

However, in the case where a high dielectric film is used as a gate insulating film, the work function of the gate electrode cannot be set near the conduction band or the valence band even when a n type impurity or a p type impurity is introduced to a gate electrode formed of a polysilicon film. More specifically, when a high dielectric film is used as a gate insulating film, the work function of the gate electrode is increased and separated from the conduction band in the n channel MISFET. Therefore, the threshold voltage of the n channel MISFET is increased. Meanwhile, the work function of the gate electrode is reduced and separated from the valence band in the p channel MISFET. Therefore, similar to the n channel MISFET, the threshold voltage thereof is increased. The phenomenon that the work function of the gate electrode shifts in a direction where a threshold voltage of a MISFET increases as described above is interpreted as Fermi level pinning. This Fermi level pinning is observed particularly in the p channel MISFET. That is, the increase in threshold voltage in the case where a high dielectric film is used to form a gate insulating film is observed particularly in the p channel MISFET. Further, when a silicon oxide film is used as a gate insulating film, the threshold voltage of the MISFET can be controlled by segregating a conductive impurity at an interface between the gate electrode (polysilicon film) and the gate insulating film. Meanwhile, when a high dielectric film is used as a gate insulating film, the effect of controlling the threshold voltage by segregating a conductive impurity at an interface between the gate electrode (polysilicon film) and the gate insulating film almost disappears due to the Fermi level pinning.

Accordingly, the threshold voltage of the MISFET is increased and the low power consumption design of the MISFET becomes difficult. In particular, the low power consumption design is difficult in a CMIS circuit in which a n channel MISFET and a p channel MISFET are formed.

It is thought that the Fermi level pinning depends on the amount of silicon contained in the gate electrode formed on the gate insulating film formed of a high dielectric film. Therefore, the reduction of Fermi level pinning by decreasing the amount of silicon contained in the gate electrode in a p channel MISFET has been examined. For example, Japanese Patent Application No. 2004-292420 discloses a technology for reducing the Fermi level pinning by forming a gate electrode from a platinum-rich silicide film. More specifically, by using a platinum-rich silicide film in which a ratio of platinum atoms to silicon atoms is increased as a gate electrode, the threshold voltage is reduced.

Note that, in the MISFETs used in various semiconductor devices, required threshold voltages differ depending on the applications thereof. Therefore, only the use of the metal-rich silicide film to form the gate electrode is insufficient to adjust the threshold voltages of the MISFETs used for various applications.

An object of the present invention is to provide a technology capable of reducing and finely adjusting a threshold voltage of a MISFET having a gate insulating film formed of a high dielectric film with a dielectric constant higher than that of a silicon oxide film.

The above and other objects and novel characteristics of the present invention will be apparent from the description of this specification and the accompanying drawings.

The typical ones of the inventions disclosed in this application will be briefly described as follows.

A semiconductor device according to the present invention comprises a MISFET which includes: (a) a semiconductor substrate; (b) a gate insulating film formed on the semiconductor substrate and containing hafnium oxide as a main component; and (c) a gate electrode formed on the gate insulating film and composed of a metal silicide film formed through a reaction between a silicon film and a metal film. Also, a ratio of silicon atoms to metal atoms of the metal silicide film is less than 1, and a conductive impurity is introduced to the metal silicide film.

A manufacturing method of a semiconductor device according to the present invention comprises the steps of: (a) forming a gate insulating film containing hafnium oxide as a main component on a semiconductor substrate; (b) forming a silicon gate electrode of a MISFET on the gate insulating film; (c) introducing a conductive impurity to the silicon gate electrode; (d) forming an insulating film with a thickness larger than that of the silicon gate electrode on the semiconductor substrate, and planarizing a surface of the insulating film, thereby exposing a surface of the silicon gate electrode; (e) forming a metal film on the silicon gate electrode; and (f) performing a thermal treatment to the semiconductor substrate to react the silicon gate electrode and the metal film, thereby forming a gate electrode composed of a metal silicide film with a ratio of silicon atoms to metal atoms of less than 1 and segregating the conductive impurity near an interface between the gate insulating film and the gate electrode.

The effects obtained by typical aspects of the present invention will be briefly described below.

Since a gate electrode is formed of a metal-rich silicide film and a conductive impurity is introduced thereto, it is possible to reduce and finely adjust the threshold voltage of a MISFET even when a high dielectric film with a dielectric constant higher than that of a silicon oxide film is used as a gate insulating film.

### BRIEF DESCRIPTIONS OF THE DRAWINGS

FIG. 1 is a cross-sectional view showing a CMISFET according to an embodiment of the present invention;

FIG. 2A is a diagram showing a concentration profile of boron introduced to a gate electrode before silicide reaction;

FIG. 2B is a diagram showing a concentration profile of boron introduced to a gate electrode after the silicide reaction;

FIG. 3 is a cross-sectional view showing a manufacturing process of the CMISFET according to the embodiment;

FIG. 4 is a cross-sectional view showing a manufacturing process of the CMISFET subsequent to FIG. 3;

FIG. 5 is a cross-sectional view showing a manufacturing process of the CMISFET subsequent to FIG. 4;

FIG. 6 is a cross-sectional view showing a manufacturing process of the CMISFET subsequent to FIG. 5;

FIG. 7 is a cross-sectional view showing a manufacturing process of the CMISFET subsequent to FIG. 6;

FIG. 8 is a cross-sectional view showing a manufacturing process of the CMISFET subsequent to FIG. 7;

FIG. 9 is a cross-sectional view showing a manufacturing process of the CMISFET subsequent to FIG. 8;

FIG. 10 is a cross-sectional view showing a manufacturing process of the CMISFET subsequent to FIG. 9;

FIG. 11 is a cross-sectional view showing a manufacturing process of the CMISFET subsequent to FIG. 10;

FIG. 12 is a cross-sectional view showing a manufacturing process of the CMISFET subsequent to FIG. 11;

FIG. 13 is a cross-sectional view showing a manufacturing process of the CMISFET subsequent to FIG. 12;

FIG. 14 is a cross-sectional view showing a manufacturing process of the CMISFET subsequent to FIG. 13;

FIG. 15 is a cross-sectional view showing a manufacturing process of the CMISFET subsequent to FIG. 14;

FIG. 16 is a graph showing the relation between the gate voltage and the capacitance in the case where a hafnium aluminate film is used as a gate insulating film and each of a platinum silicide film, a platinum-rich silicide film, and a platinum-rich silicide film doped with boron is used as a gate electrode;

FIG. 17 is a graph showing the flat band voltage in the case where a hafnium aluminate film is used as a gate insulating film and each of a platinum silicide film, a platinum-rich silicide film, and a platinum-rich silicide film doped with boron is used as a gate electrode; and

FIG. 18 is a graph showing the flat band voltage and the threshold voltage in the case where a HfON film is used as a gate insulating film and each of a polysilicon film doped with a p type impurity, a platinum silicide film, a platinum-rich silicide film, and a platinum-rich silicide film doped with boron is used as a gate electrode.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

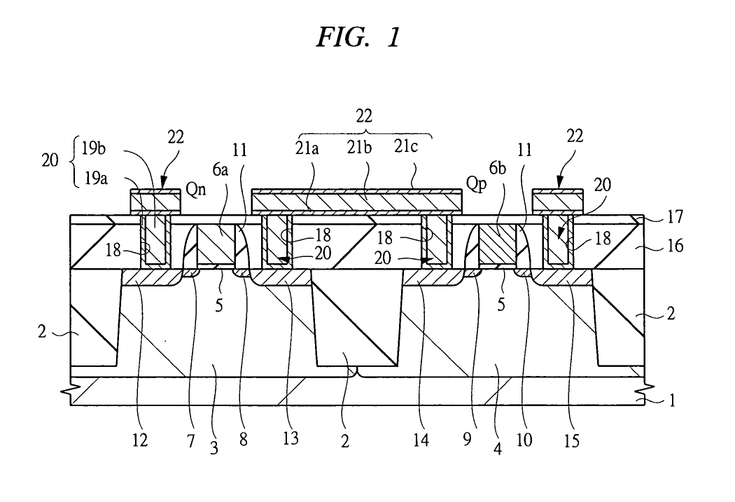

FIG. 1 is a cross-sectional view showing the structure of a MISFET according to the first embodiment. A MISFET Qn formed on the left side is a n channel MISFET and a MISFET Qp formed on the right side is a p channel MISFET.

In FIG. 1, device isolation regions 2 are formed in a semiconductor substrate 1, and a p well 3 and a n well 4 are formed in the active regions defined by the device isolation regions 2. The MISFET Qn is formed on the p well 3 and the MISFET Qp is formed on the n well 4.

The MISFET Qn has a gate insulating film 5 on the p well 3, and a gate electrode 6a is formed on the gate insulating film 5. The gate insulating film 5 is formed of a high dielectric film with a dielectric constant higher than that of a silicon oxide film.

Conventionally, a silicon oxide film has been used as a gate insulating film because of its high dielectric strength and its excellent electrical and physical stability at a silicon-silicon oxide interface.

However, along with the scaling down of the elements, the extreme reduction in thickness of the gate insulating film has been demanded. If such a silicon oxide film with a reduced thickness is used as a gate insulating film, electrons flowing in a channel of a MISFET tunnel through a barrier formed of the silicon oxide film to a gate electrode, that is, the so-called tunneling current occurs.

For its prevention, a high dielectric film made of a material with a dielectric constant higher than that of a silicon oxide film, which can increase the physical thickness without increasing the capacitance, has been used as a gate insulating film. If the high dielectric film is used as a gate insulating film, the physical thickness can be increased while keeping the same capacitance. Therefore, it is possible to reduce the leakage current.

For example, a kind of hafnium oxide such as a hafnium aluminate film (HfAlON film) is used as the high dielectric film. Alternatively, other hafnium-based insulating films such as a hafnium oxide film, a HfON film, a HfSiO film, a HfSiON film, and a HfAlO film are also available in addition to the hafnium aluminate film. Furthermore, a hafnium-based insulating film obtained by introducing such oxides as tantalum oxide, niobium oxide, titanium oxide, zirconium oxide, lanthanum oxide, and yttrium oxide into a hafnium-based insulating film is also available. Similar to the hafnium aluminate film, the hafnium-based insulating films have a dielectric constant higher than those of a silicon oxide film and a silicon oxynitride film. Therefore, the similar effects as those of the case of using the hafnium aluminate film can be achieved.

The gate electrode 6a formed on the gate insulating film 5 is formed of a nickel silicide film. As a material of a gate electrode, a polysilicon film is used in general. In this embodiment, however, a nickel silicide film which is a kind of metal silicide film is used. It is also possible to use a usual polysilicon film as a gate electrode of the MISFET Qn. In order to prevent the saturation of the drive current of the MISFET Qn due to the depletion of carriers in the gate electrode, a metal silicide film having no influences of the depletion of carriers is preferably used, and for example, a nickel silicide film is suitable. Other than the nickel silicide film, such silicide films as a platinum silicide film, an iridium silicide film, and a ruthenium silicide film are also preferable. If a polysilicon film or a nickel silicide film is used for the gate electrode 6a in the MISFET Qn in which a high dielectric film is used as the gate insulating film 5, the threshold voltage is increased due to the Fermi level pinning. However, the increase is not so significant compared to the increase in the threshold voltage in the MISFET Qp described later.

In this case, it is preferable that the ratio of silicon atoms to nickel atoms in this nickel silicide film is set to approximately 1. Although it is also preferable to set the ratio of silicon atoms to less than 1, since the work function of the gate electrode 6a changes in an increasing direction along with the relative increase of the ratio of Ni atoms in the MISFET Qn which is a n channel MISFET, the threshold voltage of the MISFET Qn is increased. For the suppression of the increase in the threshold voltage, it is preferable to set the ratio of silicon atoms to nickel atoms to approximately 1. This ratio of silicon atoms to metal atoms is true of the cases of using other metal silicide films.

Sidewalls 11 are formed on both sidewalls of the gate electrode 6a, and low-concentration n type impurity diffusion regions 7 and 8 are formed in the p well 3 below the sidewalls 11. High-concentration n type impurity diffusion regions 12 and 13 are formed outside the low-concentration n type impurity diffusion regions 7 and 8. A n type impurity (conductive impurity) such as phosphorus or arsenic is introduced to the low-concentration n type impurity diffusion regions 7 and 8 and the high-concentration n type impurity diffusion regions 12 and 13, and the concentration of the introduced n type impurity in the high-concentration n type impurity diffusion regions 12 and 13 is higher than that of the low-concentration n type impurity diffusion regions 7 and 8. A source region and a drain region of the MISFET Qn are formed from the low-concentration n type impurity diffusion regions 7 and 8 and the high-concentration n type impurity diffusion regions 12 and 13. The reason why the source region and the drain region are formed from the low-concentration n type impurity diffusion regions 7 and 8 and the high-concentration n type impurity diffusion regions 12 and 13 is to form a lightly doped drain (LDD) structure for the source region and the drain region.

Next, a structure of the MISFET Qp which is a p channel MISFET will be described. In the MISFET Qp, a gate insulating film 5 is formed on a n well 4. Similar to the gate insulating film 5 of the MISFET Qn described above, the gate insulating film 5 is formed of a high dielectric film with a dielectric constant higher than that of a silicon oxide film.

A gate electrode 6b is formed on the gate insulating film 5, and this gate electrode 6b is formed of a platinum-rich silicide film. As described above, if a high dielectric film is used as the gate insulating film 5 and a polysilicon film is used as the gate electrode 6b, the threshold voltage is increased due to the Fermi level pinning. The increase in the threshold voltage is observed particularly in the MISFET Qp as a p channel MISFET in comparison to the MISFET Qn as a n channel MISFET. More specifically, in both of the MISFET Qn and the MISFET Qp, the work function (Fermi level) of the gate electrode is fixed at a position closer to the conduction band than the center of the forbidden band of Si due to the Fermi level pinning. In the MISFET Qn, if the work function of the gate electrode is set near the conduction band, the threshold voltage can be reduced. However, even if the work function of the gate electrode is moved to the position described above from the position near the conduction band due to the Fermi level pinning, the amount of move is not so large and the increase in the threshold voltage is small. Therefore, the increase of the threshold voltage does not cause any serious problem. Meanwhile, in the MISFET Qp, the threshold voltage can be reduced when the work function of the gate electrode is set near the valence band. However, if the work function is moved to the position described above from the position near the valence band due to the Fermi level pinning, the amount of move is large in comparison to that of the MISFET Qn. Therefore, the increase in the threshold voltage is large and it causes some problems.

For its solution, in the MISFET Qp as a p channel MISFET, in consideration of the fact that the Fermi level pinning can be reduced by decreasing the amount of silicon contained in the gate electrode 6b, a platinum-rich silicide film is used as the gate electrode 6b of the MISFET Qp in this embodiment. That is, since the work function of the platinum-rich silicide film is suitable to reduce the threshold voltage of the MISFET Qp, the platinum-rich silicide film is used for the gate electrode 6b of the MISFET Qp. Further, since the Fermi level pinning is reduced by lowering the silicon content in the gate electrode 6b, the platinum-rich silicide film is used. The platinum-rich silicide film mentioned here indicates a film with the composition in which a ratio of silicon atoms to platinum atoms is less than 1. A chemical formula thereof is as follows, that is: PtSix (x<1). More specifically, the composition of the platinum-rich silicide film includes, for example, Pt₃Si, Pt₁₂Si₅, Pt₂Si and others, and a platinum-rich silicide film with the composition of Pt₃Si is preferably used for the gate electrode 6b from the viewpoint that the silicon content is lowered to reduce the Fermi level pinning. As described above, a platinum-rich silicide film is used as a material of the gate electrode 6b instead of a polysilicon film. By this means, the Fermi level pinning can be reduced, and the threshold voltage can be reduced. However, only the use of the platinum-rich silicide film for the gate electrode 6b is insufficient to achieve the fine adjustment of the threshold voltage so as to obtain a desired threshold voltage of MISFETs constituting various types of semiconductor devices.

In the case where a silicon oxide film is used as a gate insulating film and a polysilicon film is used as a gate electrode, the adjustment of the threshold voltage by segregating a conductive impurity at an interface between the gate insulating film and the gate electrode has been carried out. However, in the case where a high dielectric film is used as a gate insulating film and a polysilicon film is used as a gate electrode, the effect of adjusting the threshold voltage by segregating a conductive impurity at an interface between the gate insulating film and the gate electrode disappears because the Fermi level pinning occurs. More specifically, the effect of adjusting the threshold voltage by segregating a conductive impurity cannot be achieved. However, the inventors of the present invention have found that the threshold voltage can be adjusted by segregating a conductive impurity at an interface between a gate insulating film and a gate electrode when a high dielectric film is used for a gate insulating film and a metal-rich silicide film is used for a gate electrode. More specifically, although it has been thought that the effect by segregating a conductive impurity cannot be obtained when a high dielectric film is used as a gate insulating film because the Fermi level pinning occurs, it has been found that the effect by segregating a conductive impurity can be obtained when a metal-rich silicide film is used as a gate electrode.

Therefore, in this embodiment, a conductive impurity is introduced to the gate electrode 6b formed of a platinum-rich silicide film. More specifically, p type impurity such as boron (B) or aluminum (Al) is segregated near an interface between the gate electrode 6b and the gate insulating film 5. By this means, the threshold voltage of the MISFET Qp can be further reduced in comparison to the case where a p type impurity is not introduced. Also, since the amount of reduction of the threshold voltage can be controlled by adjusting the concentration of the p type impurity to be segregate at the interface between the gate electrode 6b and the gate insulating film 5, the fine adjustment of the threshold voltage of the MISFET Qp can be achieved. As described above, one feature of this embodiment lies in that a conductive impurity is introduced to the gate electrode 6b formed of a platinum-rich silicide film. In this embodiment, a p type impurity is introduced to the gate electrode 6b. Alternatively, for example, when a fine adjustment in a direction where the threshold voltage increases is desired, a n type impurity such as phosphorus (P), arsenic (As), or antimony (Sb) is introduced instead of a p type impurity. Also in this case, by adjusting the concentration of the n type impurity to be introduced, the fine adjustment of the threshold voltage can be achieved.

The segregation mentioned here indicates the increase of concentration of a conductive impurity present at an interface between the gate insulating film 5 and the gate electrode 6b. More specifically, when the gate electrode 6b formed of a platinum-rich silicide film is to be formed, the silicide reaction occurs from an upper portion toward a lower portion of the gate electrode 6b, and through this silicide reaction, the conductive impurity introduced to the gate electrode 6b is collected at the interface between the gate insulating film 5 and the gate electrode 6b, thereby increasing the impurity concentration at the interface.

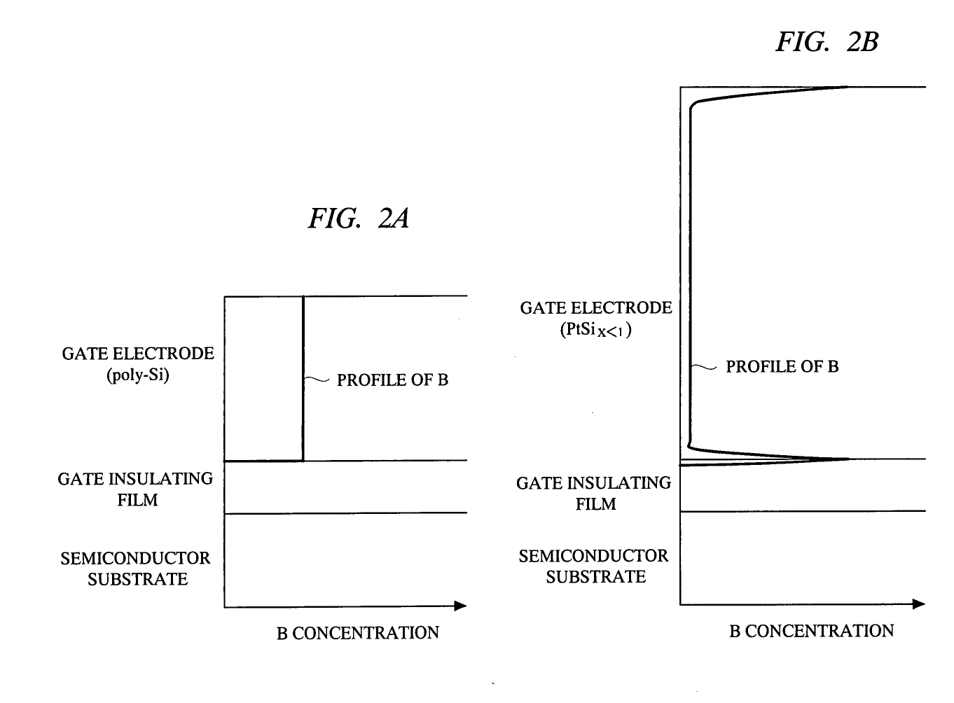

FIG. 2 shows a profile of a conductive impurity introduced to the gate electrode. In FIG. 2, the conductive impurity to be introduced to the gate electrode is a p type impurity such as boron (B). FIG. 2A shows a concentration profile of boron introduced to the gate electrode (gate electrode formed of a polysilicon film) before the silicide reaction. In FIG. 2A, the vertical axis represents a position from a semiconductor substrate. That is, a gate insulating film formed of a high dielectric film is formed on a semiconductor substrate, and a gate electrode formed of a polysilicon film is formed on the gate insulating film. Also, the horizontal axis represents the concentration of boron. As shown in FIG. 2A, before the silicide reaction, boron is uniformly introduced to the gate electrode from the surface to the interface with the gate insulating film.

Meanwhile, FIG. 2B shows a concentration profile of boron introduced to the gate electrode (gate electrode formed of a platinum-rich silicide film) after the silicide reaction. As shown in FIG. 2B, in the gate electrode after the silicide reaction, the concentration of boron is not uniform from the surface to the interface with the gate insulating film, and the concentration of boron is increased at the interface between the gate electrode and the gate insulating film. In other words, in the gate electrode after the silicide reaction, boron as a conductive impurity is segregated at the interface between the gate electrode and the gate insulating film.

Next, in the MISFET Qp in FIG. 1, sidewalls 11 are formed on both sidewalls of the gate electrode 6b, and low-concentration p type impurity diffusion regions 9 and 10 are formed in the n well 4 below the sidewalls 11. Also, high-concentration p type impurity diffusion regions 14 and 15 are formed outside the low-concentration p type impurity diffusion regions 9 and 10. A p type impurity (conductive impurity) such as boron is introduced to the low-concentration p type impurity diffusion regions 9 and 10 and the high-concentration p type impurity diffusion regions 14 and 15, and the concentration of the introduced p type impurity in the high-concentration p type impurity diffusion regions 14 and 15 is higher than that of the low-concentration p type impurity diffusion regions 9 and 10. A source region and a drain region of the MISFET Qp are formed from the low-concentration p type impurity diffusion regions 9 and 10 and the high-concentration p type impurity diffusion regions 14 and 15. The reason why the source region and the drain region are formed from the low-concentration p type impurity diffusion regions 9 and 10 and the high-concentration p type impurity diffusion regions 14 and 15 is to form a lightly doped drain (LDD) structure for the source region and the drain region.

The MISFET Qn and the MISFET Qp have the structure as described above, and insulating films 16 and 17 formed of, for example, silicon oxide films are formed so as to cover the MISFET Qn and the MISFET Qp. Also, contact holes 18 are formed so as to penetrate the insulating films 16 and 17. The contact holes 18 reach the high-concentration n type impurity regions 12 and 13 and the high-concentration p type impurity regions 14 and 15. A titanium/titanium nitride film 19 and a tungsten film 19b are filled in the contact holes 18, thereby forming plugs 20. Then, wires 22 are formed so as to be connected to the plugs 20. The wires 22 are formed from a laminated film of a titanium/titanium nitride film 21a, an aluminum film 21b, and a titanium/titanium nitride film 21c.

Next, the manufacturing method of a CMISFET according to this embodiment will be described with reference to the drawings.

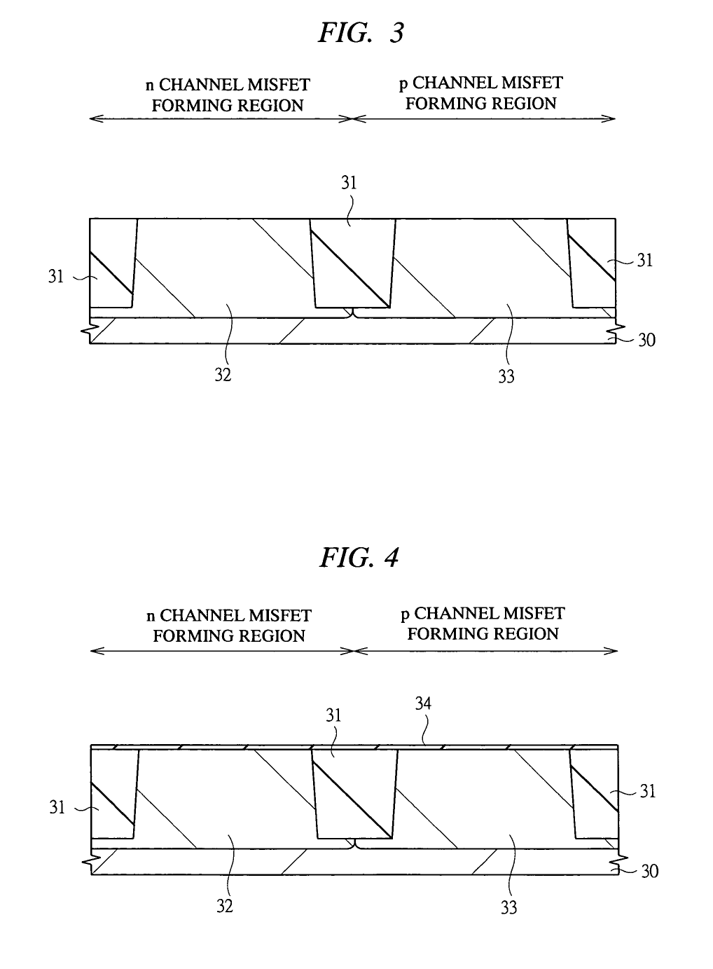

First, as shown in FIG. 3, device isolation regions 31 are formed in a main surface of a semiconductor substrate 30 made of p type single crystal silicon by the known shallow trench isolation (STI). The device isolation regions 31 are formed by forming trenches, filling the trenches with a silicon oxide film, and then polishing the surface of the semiconductor substrate 30 through chemical mechanical polishing (CMP).

Next, boron is ion-implanted into a n channel MISFET forming region of the semiconductor substrate 30, and phosphorus is ion-implanted into a p channel MISFET forming region of the semiconductor substrate 30. Subsequently, thermal treatment is performed to the semiconductor substrate 30 to diffuse boron and phosphorus within the semiconductor substrate 30, thereby forming a p well 32 and a n well 33.

Thereafter, an impurity for adjusting the threshold voltage of the MISFET is ion-implanted into the respective surfaces of the p well 32 and the n well 33. Then, as shown in FIG. 4, a gate insulating film 34 formed of a hafnium aluminate film is formed on the respective surfaces of the p well 32 and the n well 33. The hafnium aluminate film can be formed through chemical vapor deposition (CVD) or atomic layer deposition (ALD).

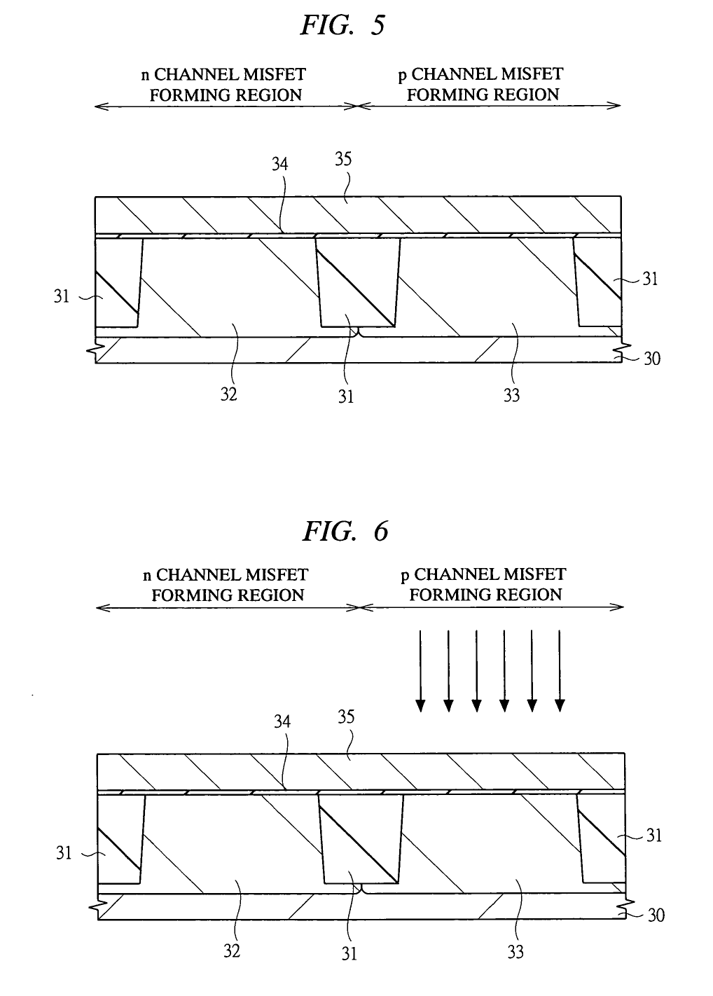

Next, as shown in FIG. 5, a polysilicon film 35 is formed on the gate insulating film 34. The polysilicon film 35 can be formed through, for example, CVD and has a thickness of, for example, 50 nm. Subsequently, as shown in FIG. 6, a conductive impurity such as boron (B) is ion-implanted into the p channel MISFET forming region of the semiconductor substrate 30. At this time, the dose amount of the conductive impurity is, for example, 5×10¹⁴ to 5×10¹⁵/cm².

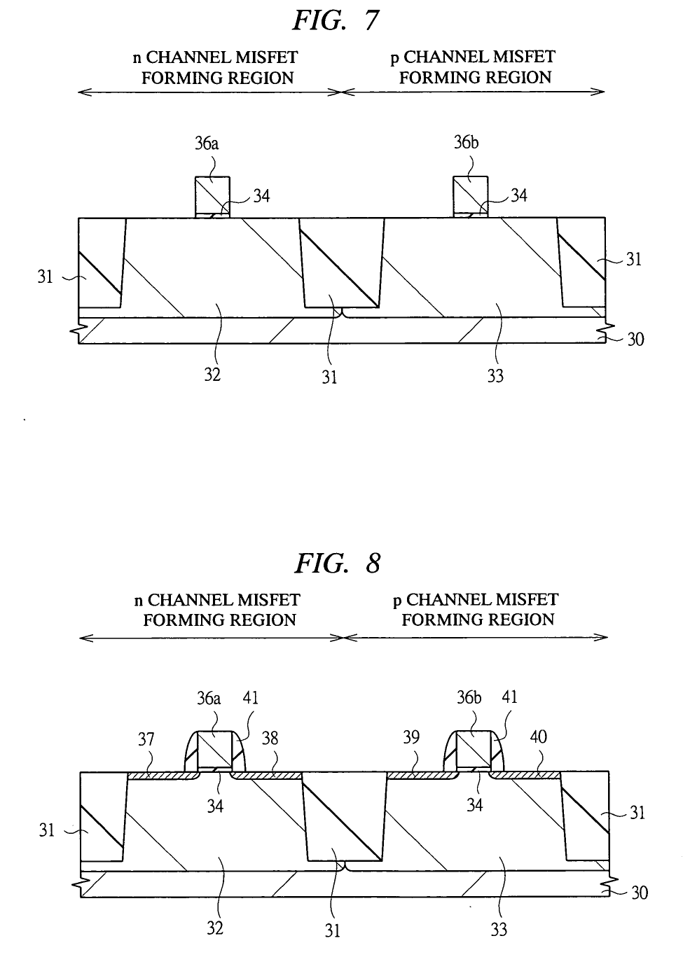

Next, as shown in FIG. 7, silicon gate electrodes 36a and 36b are formed through the photolithography process and the etching process. Subsequently, as shown in FIG. 8, phosphorus or arsenic is ion-implanted into the p well 32 to form low-concentration n type impurity diffusion regions 37 and 38. Similarly, boron is ion-implanted into the n well 33 to form low-concentration p type impurity diffusion regions 39 and 40. Thereafter, sidewalls 41 are formed on the sidewalls of the silicon gate electrodes 36a and 36b. The sidewalls 41 are formed by forming a silicon oxide film on the semiconductor substrate 30 through CVD and then performing the anisotropic etching to the formed silicon oxide film.

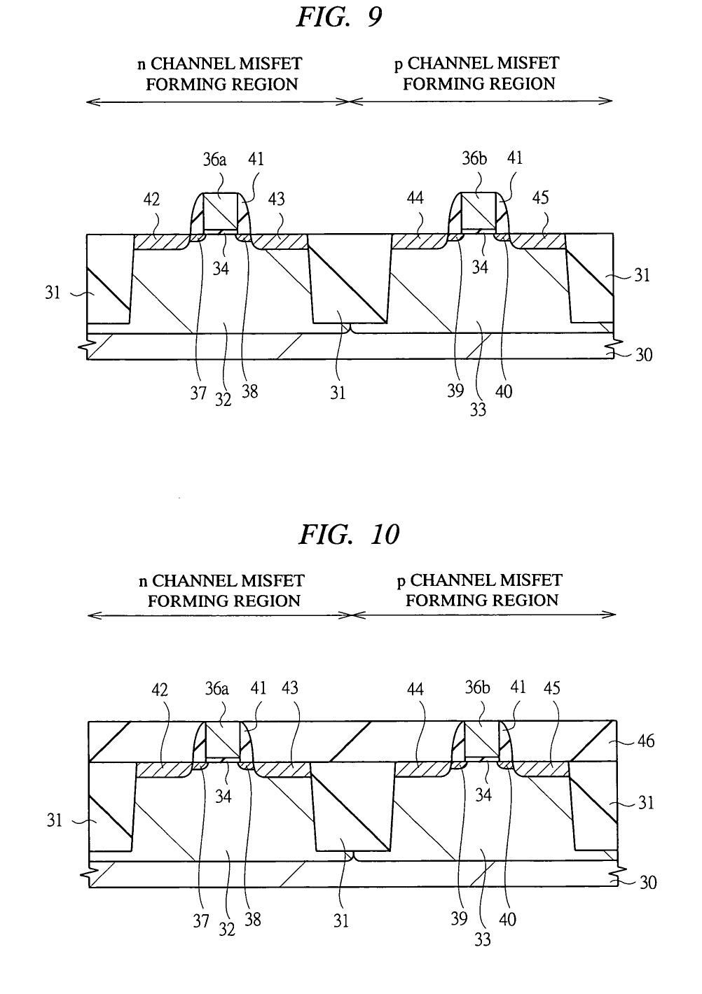

Next, as shown in FIG. 9, phosphorus or arsenic is ion-implanted into the p well 32, and boron is ion-implanted into the n well 33. Then, the thermal treatment is performed to the semiconductor substrate 30 to diffuse the implanted impurities, thereby forming high-concentration n type impurity diffusion regions 42 and 43 in the p well 32 and forming high-concentration p type impurity diffusion regions 44 and 45 in the n well 33.

Next, as shown in FIG. 10, after forming a silicon oxide film 46 on the semiconductor substrate 30 through CVD, the surface of the silicon oxide film 46 is polished and planarized through CMP, thereby exposing the surfaces of the silicon gate electrodes 36a and 36b.

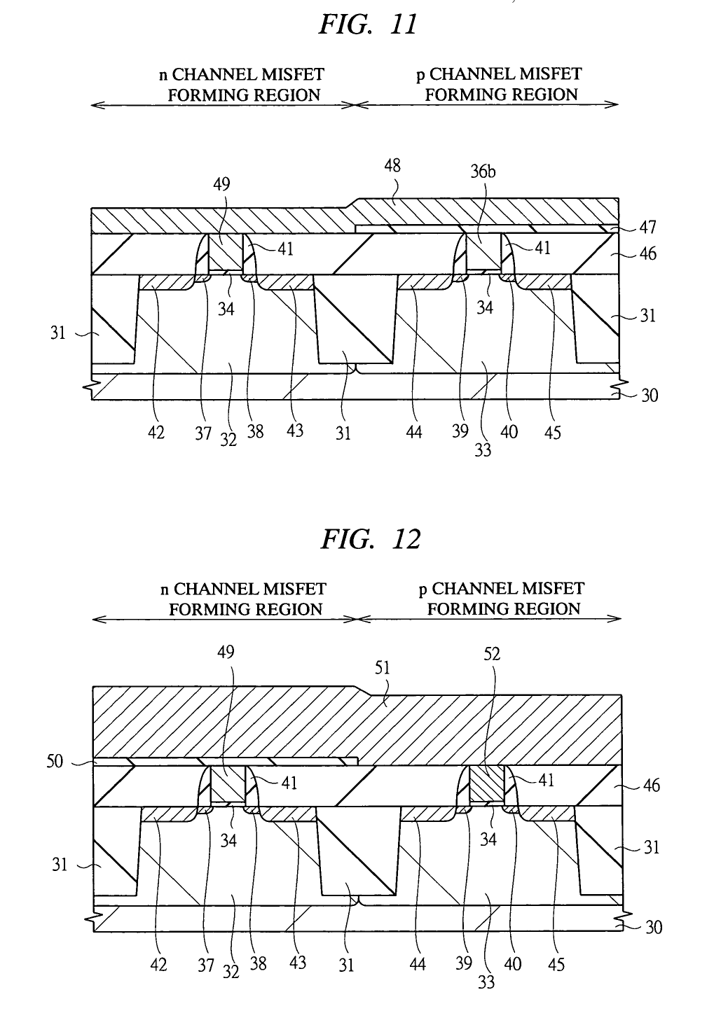

Then, after forming an insulating film 47 on the silicon oxide film 46 through CVD, the insulating film 47 is patterned through the photolithography process and the etching process. This patterning is performed so that the insulating film 47 is left only on the p channel MISFET forming region. Subsequently, as shown in FIG. 11, a nickel film 48 is formed on the semiconductor substrate 30 through sputtering process. This nickel film 48 has a thickness of, for example, 35 nm. At this time, the silicon gate electrode 36a formed in the n channel MISFET forming region is in direct contact with the nickel film 48. However, since the insulating film 47 is formed on the silicon gate electrode 36b formed in the p channel MISFET forming region, the silicon gate electrode 36b is not in direct contact with the nickel film 48.

Next, a thermal treatment at about 400° C. is performed to the semiconductor substrate 30. By this means, the silicide reaction occurs in the silicon gate electrode 36a in direct contact with the nickel film 48, and a gate electrode 49 formed of a nickel silicide film is formed. By setting the thickness of the nickel film 48 as large as 60 to 70% of that of the silicon gate electrode 36a, the nickel silicide film formed through the reaction between the silicon gate electrode 36a and the nickel film 48 has a ratio of silicon atoms to nickel atoms of approximately 1 (NiSix: x=1). On the other hand, the silicide reaction does not occur in the silicon gate electrode 36b which is not in direct contact with the nickel film 48.

Subsequently, after removing the nickel film 48 by using, for example, mixture of sulfuric acid and hydrogen peroxide, the patterned insulating film 47 is etched and removed. Thereafter, an insulating film 50 is formed on the semiconductor substrate 30 through CVD. Then, the insulating film 50 is patterned through the photolithography process and the etching process. This patterning is performed so that the insulating film 50 is left only on the n channel MISFET forming region.

Next, a platinum film 51 is formed on the semiconductor substrate 30 through sputtering process. At this time, the silicon gate electrode 36b formed in the p channel MISFET forming region is in direct contact with the platinum film 51. However, since the insulating film 50 is formed on the gate electrode 49 formed in the n channel MISFET forming region, the gate electrode 49 is not in direct contact with the platinum film 51. The platinum film 51 is formed to have a thickness of twice (100 nm) as large as that of the silicon gate electrode 36b (50 nm), more desirably, three times (150 nm) as large as that of the silicon gate electrode 36a.

Subsequently, a thermal treatment at about 400° C. is performed to the semiconductor substrate 30. By this means, the silicide reaction occurs in the silicon gate electrode 36b in direct contact with the platinum film 51, and a gate electrode 52 formed of a platinum-rich silicide film is formed. Since the platinum film 51 is sufficiently thick in comparison to the silicon gate electrode 36a, the platinum silicide film formed through the reaction between the silicon gate electrode 36b and the platinum film 51 has a ratio of silicon atoms to platinum atoms of less than 1 (PtSix: x<1). In this manner, the gate electrode 52 formed of a platinum-rich silicide film is formed through the reaction between the silicon gate electrode 36b and the platinum film 51. In this case, boron as a conductive impurity is introduced to the silicon gate electrode 36b before the silicide reaction, and the boron is almost uniformly introduced throughout the silicon gate electrode 36b. However, the boron is segregated at the interface of the gate insulating film 34 due to the above-described silicide reaction between the silicon gate electrode 36b and the platinum film 51. More specifically, the silicide reaction occurs from an upper surface of the silicon gate electrode 36b toward the interface with the gate insulating film 34. At this time, the boron introduced to the silicon gate electrode 36b is collected at the interface between the silicon gate electrode 36b and the gate insulating film 34 through the silicide reaction. In this manner, boron is segregated at the interface between the gate electrode 52 and the gate insulating film 34 while forming the gate electrode 52 formed of a platinum-rich silicide film.

Next, as shown in FIG. 13, the unreacted platinum film 51 is removed through wet etching process using strong acid (aqua regia) or CMP, and then the insulating film 50 is etched and removed. By this means, the surfaces of the gate electrode 49 formed of a nickel silicide film and the gate electrode 52 formed of a platinum-rich silicide film are exposed.

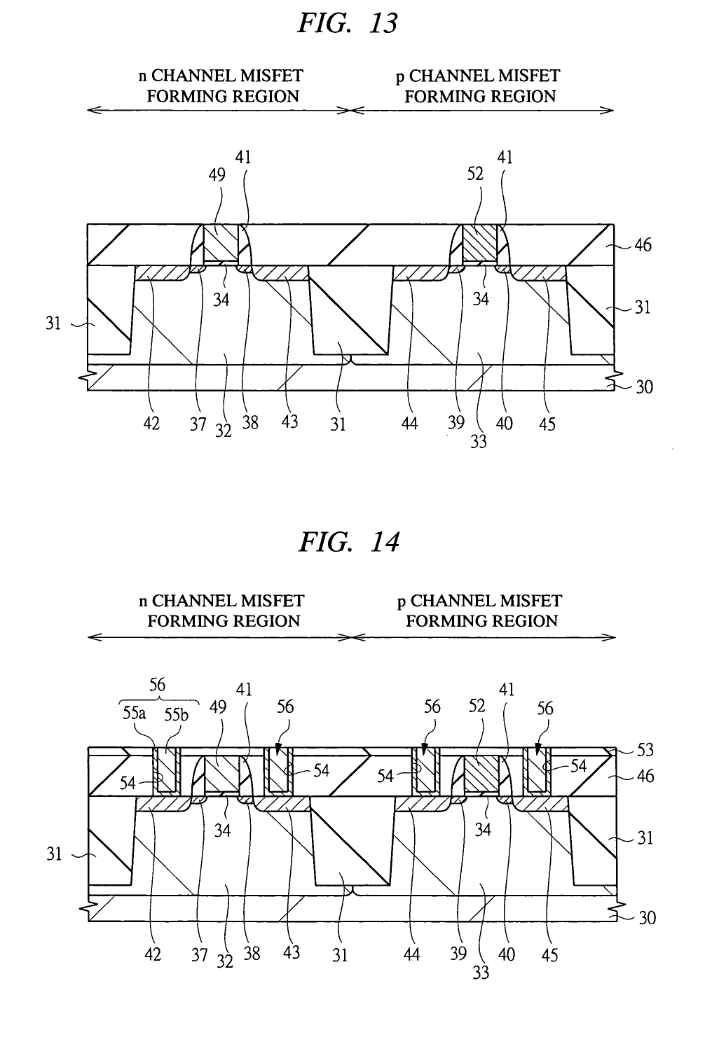

Next, as shown in FIG. 14, a silicon film 53 is formed on the silicon oxide film 46 through, for example, CVD. Then, contact holes 54 are formed in the silicon film 46 and the silicon oxide film 53 through the photolithography process and the etching process. Thereafter, a titanium/titanium nitride film 55a is formed in the contact holes 54 and on the silicon oxide film 53 through, for example, sputtering process. Subsequently, a tungsten film 55b is formed on the titanium/titanium nitride film 55a through, for example, CVD. In this manner, the contact holes 54 are filled with the titanium/titanium nitride film 55a and the tungsten film 55b. Then, the titanium/titanium nitride film 55a and the tungsten film 55b formed on the silicon oxide film 53 are removed through CMP. By this means, the titanium/titanium nitride film 55a and the tungsten film 55b are left only in the contact holes 54, thereby forming plugs 56.

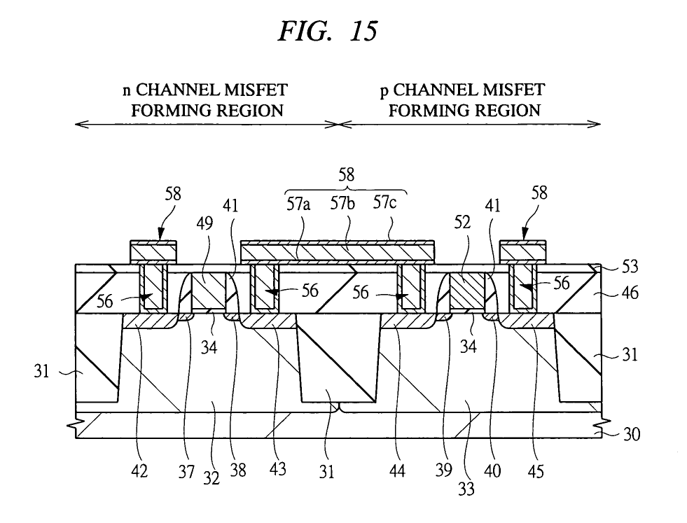

Next, as shown in FIG. 15, a laminated film of a titanium/titanium nitride film 57a, an aluminum film 57b, and a titanium/titanium nitride film 57c is formed on the silicon oxide film 53. Then, the laminated film is patterned through the photolithography process and the etching process, thereby forming wires 58. Through the process as described above, the CMISFET according to this embodiment is completed.

Next, the reduction of the threshold voltage in the p channel MISFET according to this embodiment will be described.

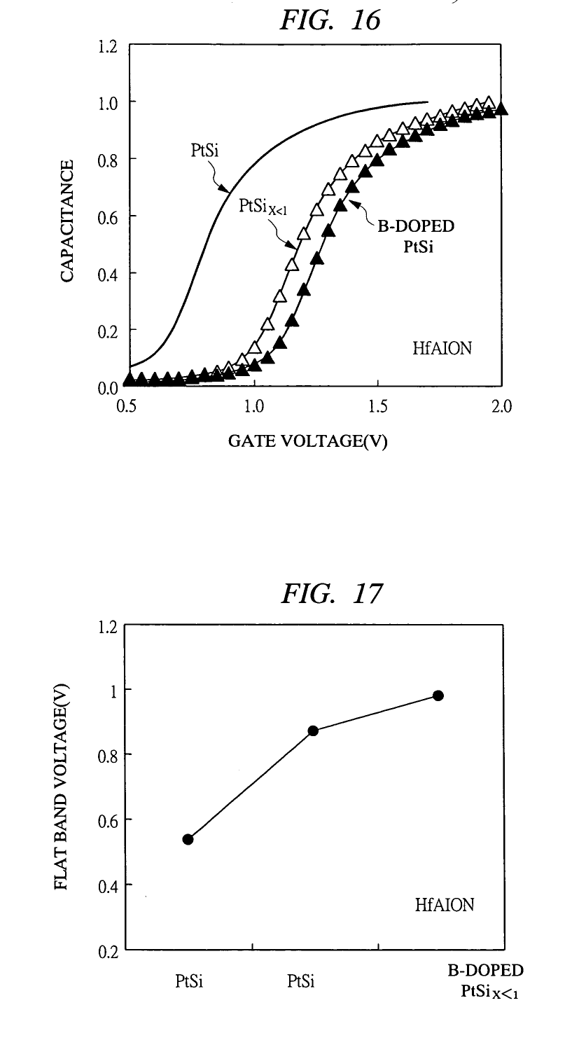

FIG. 16 is a graph showing the relation between the gate voltage (V) and the capacitance of the p channel MISFET in which a hafnium aluminate film is used as a gate insulating film. In FIG. 16, the vertical axis represents the capacitance and the horizontal axis represents the gate voltage. FIG. 16 shows the relation between the gate voltage (V) and the capacitance in each of the cases where a platinum silicide film (PtSix: x=1) is used as a gate electrode, a platinum-rich silicide film (PtSix: x<1) is used as a gate electrode, and a platinum-rich silicide film doped with boron (B) is used as a gate electrode. As shown in FIG. 16, in comparison to a curve of the case where a platinum silicide film is used as a gate electrode, a curve of the case where a platinum-rich silicide film is used as a gate electrode is shifted in a positive direction of the gate voltage. In this case, the more the relation between the gate voltage and the capacitance of the p channel MISFET is shifted in a positive direction of the gate voltage, the more the threshold voltage of the p channel MISFET is reduced. Therefore, the threshold voltage can be reduced more when a platinum-rich silicide film is used as a gate electrode than when a platinum silicide film is used as a gate electrode. Furthermore, in the case where a platinum-rich silicide film is used as a gate electrode and boron is introduced thereto, the curve is shifted more in a positive direction of the gate voltage than the case where a platinum-rich silicide film is used as a gate electrode and boron is not introduced thereto. Therefore, it can be understood that the threshold voltage of the p channel MISFET can be further reduced by introducing boron.

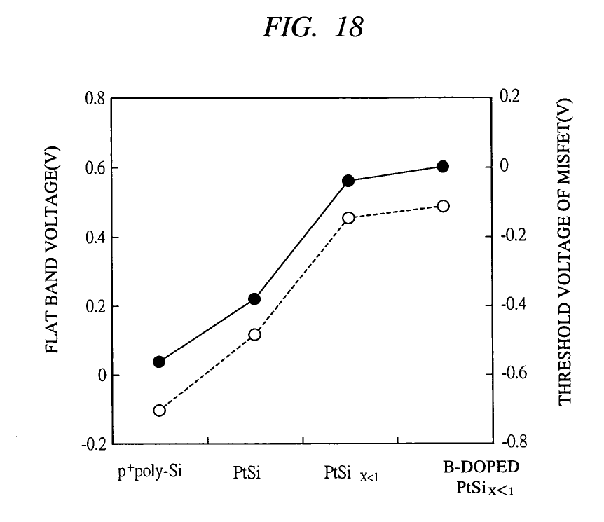

FIG. 17 shows flat band voltage (V) in each of the cases where a platinum silicide film is used as a gate electrode, a platinum-rich silicide film is used as a gate electrode, and a platinum-rich silicide film doped with boron (B) is used as a gate electrode. In FIG. 17, the flat band voltage in the case where a platinum silicide film is used as a gate electrode is about 0.55 V, and the flat band voltage in the case where a platinum-rich silicide film is used as a gate electrode is about 0.9 V. Further, the flat band voltage in the case where a platinum-rich silicide film is used as a gate electrode and boron is introduced thereto is about 1.0 V. In the case of the p channel MISFET, the more the flat band voltage is shifted in a positive direction, the more the threshold voltage is reduced. Therefore, it can be understood that the threshold voltage can be reduced most when a platinum-rich silicide film is used as a gate electrode and boron is introduced thereto. More specifically, the voltage shift of about 0.35 V can be achieved by changing a platinum silicide film to a platinum-rich silicide film, and the voltage shift of about 0.1 V can be achieved by introducing boron to a platinum-rich silicide film. As described above, it can be understood from FIG. 16 and FIG. 17 that the threshold voltage can be finely adjusted by introducing a conductive impurity to a platinum-rich silicide film.

FIG. 18 is a graph showing the flat band voltage (V) and the threshold voltage (V) of the p channel MISFET in the case where a hafnium oxynitride film (HfON film) is used as a gate insulating film. The flat band voltage (V) and the threshold voltage (V) in each of the cases where a polysilicon film doped with a p type impurity is used as a gate electrode, a platinum silicide film is used as a gate electrode, a platinum-rich silicide film is used as a gate electrode, and a platinum-rich silicide film doped with boron is used as a gate electrode are shown in FIG. 18. Black circles represent the flat band voltages and white circles represent the threshold voltages.

As shown in FIG. 18, it can be understood that the flat band voltage is increased in order of a polysilicon film doped with a p type impurity, a platinum silicide film, a platinum-rich silicide film, and a platinum-rich silicide film doped with boron. The same is true of the threshold voltage. That is, the absolute value of the threshold voltage is lowest in the platinum-rich silicide film doped with boron. In other words, it can be understood that, when a high dielectric film is used for a gate insulating film, the threshold voltage can be finely adjusted by introducing a conductive impurity such as boron to a platinum-rich silicide film forming a gate electrode.

According to this embodiment, the threshold voltage can be adjusted by using a platinum-rich silicide film containing a conductive impurity as a gate electrode. Consequently, since the threshold voltage can be adjusted, it is possible to manufacture a semiconductor device with high ON current and low threshold voltage. Also, it is possible to achieve the threshold voltage required in various semiconductor devices.

In this embodiment, the case where a conductive impurity (for example, boron) is introduced to the gate electrode 52 formed of a platinum-rich silicide film in a p channel MISFET has been described. Further, similar effects can be achieved even when a conductive impurity is introduced to a nickel-rich silicide film, a ruthenium-rich silicide film, or an iridium-rich silicide film instead of a platinum-rich silicide film.

Also, in this embodiment, as shown in FIG. 6, the case where boron is introduced to the polysilicon film 35 in the p channel MISFET forming region has been described. However, the present invention is not limited to this. For example, boron can be introduced to the silicon gate electrode 36b when forming the high-concentration p type impurity diffusion region 44 and 45 in the n well 33 as shown in FIG. 9.

Also, in this embodiment, the case where a conductive impurity is not introduced to the n channel MISFET has been described. However, it is also possible to introduce a conductive impurity to the n channel MISFET.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be widely applied to the manufacturing industry for semiconductor devices.

What is claimed is:

1. A semiconductor device having a MISFET which comprises:
(a) a semiconductor substrate;
(b) a gate insulating film formed on said semiconductor substrate and containing hafnium oxide as a main component; and
(c) a gate electrode formed on said gate insulating film and composed of a metal silicide film formed through a reaction between a silicon film and a metal film,
wherein said metal silicide film has a ratio of silicon atoms to metal atoms of less than 1, and a conductive impurity is introduced to said metal silicide film.

2. The semiconductor device according to claim 1,
wherein said metal film is a platinum film, a nickel film, a ruthenium film, or an iridium film.

3. The semiconductor device according to claim 1,
wherein said conductive impurity is a p type impurity.

4. The semiconductor device according to claim 1,
wherein said conductive impurity is a n type impurity.

5. The semiconductor device according to claim 1,
wherein said conductive impurity is segregated at an interface between said gate insulating film and said gate electrode.

6. The semiconductor device according to claim 1,
wherein said MISFET is a p channel MISFET.

7. A semiconductor device having a n channel MISFET and a p channel MISFET formed on a semiconductor substrate,
wherein said p channel MISFET comprises:
(a) a gate insulating film formed on said semiconductor substrate and containing hafnium oxide as a main component; and
(b) a gate electrode formed on said gate insulating film and composed of a metal silicide film formed through a reaction between a silicon film and a metal film, and
said metal silicide film has a ratio of silicon atoms to metal atoms of less than 1, and a conductive impurity is introduced to said metal silicide film.

8. A manufacturing method of a semiconductor device, comprising the steps of:
(a) forming a gate insulating film containing hafnium oxide as a main component on a semiconductor substrate;
(b) forming a silicon gate electrode of a MISFET on said gate insulating film;
(c) introducing a conductive impurity to said silicon gate electrode;
(d) forming an insulating film with a thickness larger than that of said silicon gate electrode on said semiconductor substrate, and planarizing a surface of said insulating film, thereby exposing a surface of said silicon gate electrode;
(e) forming a metal film on said silicon gate electrode; and
(f) performing a thermal treatment to said semiconductor substrate to react said silicon gate electrode and said metal film, thereby forming a gate electrode composed of a metal silicide film with a ratio of silicon atoms to metal atoms of less than 1 and segregating said conductive impurity near an interface between said gate insulating film and said gate electrode.

9. The manufacturing method of a semiconductor device according to claim 8,
wherein a thickness of said metal film is larger than that of said silicon gate electrode.

10. The manufacturing method of a semiconductor device according to claim 9,
wherein the thickness of said metal film is more than twice as large as that of said silicon gate electrode.
